(19) United States
(12) Patent Application Publication
(10) Pub. No.: US 2026/0165064 A1
(43) Pub. Date: Jun. 11, 2026

(54) SUBSTRATE PROCESSING APPARATUS AND EXHAUST SWITCHING UNIT

(71) Applicant: SEMES CO., LTD., Cheonan-si (KR)

(72) Inventors: Seung Joo CHOI, Incheon (KR); Won Sik SON, Hwaseong-si (KR); Jae Youl KIM, Yongin-si (KR); In Ki JUNG, Seongnam-si (KR); Ho Jong HWANG, Hwaseong-si (KR); Won Geun KIM, Goyang-si (KR); Se Hoon OH, Cheonan-si (KR)

(73) Assignee: SEMES CO., LTD., Cheonan-si (KR)

(21) Appl. No.: 19/414,847

(22) Filed: Dec. 10, 2025

(30) Foreign Application Priority Data
Dec. 11, 2024 (KR) 10-2024-0183791

(51) Int. Cl. H10P 72/00

(52) U.S. Cl. CPC H10P 72/0402; H10P 72/0414

(57) ABSTRACT

Provided is a substrate processing apparatus including: a liquid treating chamber for processing a substrate with multiple types of treatment liquids; an individual exhaust pipe connected to the liquid treating chamber to exhaust an atmosphere in the liquid treating chamber; a plurality of collective exhaust pipes connected to the individual exhaust pipes; and an exhaust switching unit which is disposed between the individual exhaust pipe and the collective exhaust pipe, and switches an exhaust path of the exhaust gas to a corresponding collective exhaust pipe according to the property of the exhaust gas flowing in the individual exhaust pipe, in which the exhaust switching unit includes an exhaust switching module disposed between the individual exhaust pipe and each of the collective exhaust pipes.

### CROSS-REFERENCE TO RELATED APPLICATION

This application claims priority to and the benefit of Korean Patent Application No. 10-2024-0183791 filed in the Korean Intellectual Property Office on Dec. 11, 2024, the entire contents of which are incorporated herein by reference.

### TECHNICAL FIELD

The present invention relates to an apparatus for processing a substrate and an exhaust switching unit, and more particularly, to a substrate processing apparatus and an exhaust switching unit capable of switching an exhaust path.

### BACKGROUND ART

To manufacture a semiconductor device or liquid crystal display, various processes, such as photolithography, etching, ashing, ion implantation, and thin film deposition, are performed on a substrate. Before or after such a process proceeds, a cleaning process is performed to clean the substrate to remove contaminants and particles generated in each process. In general, the cleaning process includes a process of liquid-treating a substrate. The liquid used in the cleaning process includes chemicals having acid or basic properties and an organic solvent. Hazardous gas with acid/base/organic properties generated after substrate processing cause environmental problems, so they need to be separated and discharged.

In addition, unintended by-products may be generated by chemical reactions of gas with different properties that make up the exhaust, resulting in contamination of the exhaust path, so it is necessary to separate the exhaust paths of the exhaust gas of different properties while minimizing contamination of the exhaust path.

### SUMMARY OF THE INVENTION

The present invention has been made in an effort to provide a substrate processing apparatus and an exhaust switching unit capable of separating and switching an exhaust path according to properties of exhaust gas.

The present invention has also been made in an effort to provide a substrate processing apparatus and an exhaust switching unit capable of preventing exhaust gas of different properties from reacting.

The present invention has also been made in an effort to provide a substrate processing apparatus and an exhaust switching unit capable of minimizing contamination of an exhaust path.

The present invention has also been made in an effort to provide a substrate processing apparatus and an exhaust switching unit capable of suppressing pressure fluctuation in an exhaust path.

The objectives of the present disclosure are not limited thereto and other objectives not stated herein may be clearly understood by those skilled in the art from the following description.

An exemplary embodiment of the present disclosure, a substrate processing apparatus comprising: a liquid treating chamber for processing a substrate with multiple types of treatment liquids; an individual exhaust pipe connected to the liquid treating chamber to exhaust an atmosphere in the liquid treating chamber; a plurality of collective exhaust pipes connected to the individual exhaust pipes; and an exhaust switching unit which is disposed between the individual exhaust pipe and the collective exhaust pipe, and switches an exhaust path of the exhaust gas to a corresponding collective exhaust pipe according to the property of the exhaust gas flowing in the individual exhaust pipe, wherein the exhaust switching unit includes an exhaust switching module disposed between the individual exhaust pipe and each of the collective exhaust pipes, each of the exhaust switching modules includes: a housing in which a first space and a second space separated and partitioned from each other by a partition wall are formed; a switching valve provided inside the housing; and a valve driver for driving the switching valve between a first state and a second state, the first space is provided as a space capable of communicating with the individual exhaust pipe, the second space is provided as a space through which outside air is introduced, the first state is a state in which the exhaust switching module makes the individual exhaust pipe communicate with the collective exhaust pipe, and the second state may be a state in which the exhaust switching module makes the outside communicate with the collective exhaust pipe.

According to the exemplary embodiment of the present invention, wherein the housing includes: an exhaust inlet through which the exhaust gas is introduced from the individual exhaust pipe; an exhaust outlet through which the exhaust gas introduced into the housing is discharged; an outside air inlet through which outside air is introduced into the housing; and an outside air outlet through which the outside air introduced into the housing is discharged, the exhaust inlet and the exhaust outlet are provided in the first space, the outside air inlet and the outside air outlet are provided in the second space, and the exhaust outlet and the outside air outlet may communicate with the collective exhaust pipe.

According to the exemplary embodiment of the present invention, wherein the exhaust switching module is provided to be switched between a first state and a second state through rotation of the switching valve, the first state is a state in which the exhaust inlet is opened and the outside air inlet is closed, and the second state is a state in which the exhaust inlet is closed and the outside air inlet may be opened.

According to the exemplary embodiment of the present invention, wherein the switching valve is provided in a cylindrical shape passing through the first space and the second space, and may be provided to rotate around a central axis.

According to the exemplary embodiment of the present invention, wherein the switching valve may be formed with: a first passage through which the exhaust gas introduced into the first space through the exhaust inlet flows to the exhaust outlet; and a second passage through which the outside air introduced into the second space through the outside air inlet flows to the outside air outlet.

According to the exemplary embodiment of the present invention, wherein the first passage and the second passage of the switching valve may be provided in a curved shape.

According to the exemplary embodiment of the present invention, wherein the outside air inlet may be directly exposed to ambient.

According to the exemplary embodiment of the present invention, wherein the exhaust switching unit further may includes a buffer module having a buffer space provided between the individual exhaust pipe and the plurality of exhaust switching modules.

According to the exemplary embodiment of the present invention, wherein the buffer module may includes an outside air compensation module that introduces outside air into the buffer space.

According to the exemplary embodiment of the present invention, wherein the collective exhaust pipe may includes: a first collective pipe for exhausting acid gas; a second collective pipe for exhausting alkaline gas; and a third collective pipe for exhausting organic gas.

According to the exemplary embodiment of the present invention, wherein the liquid treating chamber is provided in plural, the plurality of liquid treating chambers is stacked and provided, a frame surrounding the plurality of stacked liquid treating chambers is included, and the collective exhaust pipe and the exhaust switching unit may be disposed above the frame.

According to the exemplary embodiment of the present invention, further comprising: a pipe cleaning units for cleaning the individual exhaust pipe; and a controller, the pipe cleaning unit includes a plurality of cleaning liquid injection nozzles that supplies a cleaning liquid to the individual exhaust pipe, the cleaning liquid injection nozzle is installed inside the individual exhaust pipe, and the controller calculates the amount of by-products that may be generated according to the amount of treatment liquid supplied to the liquid treating chamber, and may controls the cleaning liquid injection nozzle to supply the amount of cleaning liquid needed to dissolve the calculated amount of by-products.

According to the exemplary embodiment of the present invention, further comprising: a controller, wherein, according to a property of the exhaust gas flowing in the individual exhaust pipe, the controller controls an exhaust switching module corresponding to the exhaust gas among the plurality of exhaust switching modules to be switched to the first state, and may controls the remaining exhaust switching modules except for the exhaust switching module corresponding to the exhaust gas to be switched to the second state.

According to the exemplary embodiment of the present invention, further comprising: a controller, when a flow rate of the exhaust gas introduced into the buffer space from the individual exhaust pipe is reduced, the controller may controls the reduced flow rate to be compensated by introducing outside air into the buffer space through the outside air compensation module.

An exemplary embodiment of the present disclosure, an exhaust switching unit that is connected to an individual exhaust pipe and separates and discharges exhaust gas according to a property of the exhaust gas flowing in the individual exhaust pipe, the exhaust switching unit comprising: a plurality of exhaust switching modules provided to correspond to the property of the exhaust gas, wherein each of the exhaust switching modules includes: a housing in which a first space and a second space separated and partitioned from each other are formed; a switching valve provided inside the housing; and a valve driver for driving the switching valve between a first state and a second state, the housing includes: an exhaust inlet through which the exhaust gas is introduced from the individual exhaust pipe; an exhaust outlet through which the exhaust gas introduced into the housing is discharged; an outside air inlet through which outside air is introduced into the housing; and an outside air outlet through which the outside air introduced into the housing is discharged, the exhaust inlet and the exhaust outlet are provided in the first space, the outside air inlet and the outside air outlet are provided in the second space, the switching valve is provided in a cylindrical shape passing through the first space and the second space, the switching valve is formed with: a first groove that is a first passage through which the exhaust gas introduced into the first space through the exhaust inlet flows to the exhaust outlet; and a second groove that is a second passage through which the outside air introduced into the second space through the outside air inlet flows to the outside air outlet, and the first groove and the second groove may be provided in a curved shape.

According to the exemplary embodiment of the present invention, wherein the exhaust switching module is provided to be switched between the first state and the second state through rotation of the switching valve, the switching valve is provided to rotate around a central axis, the first state is a state in which the exhaust inlet and the exhaust outlet are opened and the outside air inlet and the outside air outlet are closed, and the second state is a state in which the exhaust inlet and the exhaust outlet are closed and the outside air inlet and the outside air outlet may be opened.

According to the exemplary embodiment of the present invention, further comprising: a buffer module having a buffer space provided between the individual exhaust pipe and the plurality of exhaust switching modules, wherein the buffer module may includes an outside air compensation module that introduces outside air into the buffer space.

An exemplary embodiment of the present disclosure, a substrate processing apparatus comprising: a liquid treating chamber for processing a substrate with multiple types of treatment liquids; an individual exhaust pipe connected to the liquid treating chamber to exhaust an atmosphere in the liquid treating chamber; a plurality of collective exhaust pipes connected to the individual exhaust pipe to exhaust exhaust gas exhausted from a plurality of liquid treating chambers; and an exhaust switching unit which is connected to the individual exhaust pipe and the collective exhaust pipe and switches an exhaust path of the exhaust gas to a collective exhaust pipe corresponding to the exhaust gas according to a property of the exhaust gas flowing in the individual exhaust pipe, the liquid treating chamber and the individual exhaust pipe are provided in plural, the exhaust switching unit connects each of the individual exhaust pipes to the collective exhaust pipe, the exhaust switching unit includes: a plurality of exhaust switching modules provided to correspond to the property of the exhaust gas; and a buffer module having a buffer space provided between the individual exhaust pipe and the plurality of exhaust switching modules, each of the exhaust switching modules includes: a housing in which a first space and a second space separated and partitioned from each other are formed; a switching valve provided inside the housing; and a valve driver which drives the switching valve between a first state and a second state, the housing includes: an exhaust inlet through which the exhaust gas is introduced from the individual exhaust pipe; an exhaust outlet through which the exhaust gas introduced into the housing is discharged; an outside air inlet through which outside air is introduced into the housing; and an outside air outlet through which the outside air introduced into the housing is discharged, the exhaust inlet and the exhaust outlet are provided in the first space, the outside air inlet and the outside air outlet are provided in the second space, the exhaust outlet and the outside air outlet communicate with the collective exhaust pipe, the exhaust switching module is provided to be switched between the first state and the second state through rotation of the switching valve, the first state is a state in which the exhaust inlet and the exhaust outlet are opened and the outside air inlet and the outside air outlet are closed, the second state is a state in which the exhaust inlet and the exhaust outlet are closed and the outside air inlet and the outside air outlet are opened, and the buffer module may includes an outside air compensation module that introduces outside air into the buffer space.

According to the exemplary embodiment of the present invention, wherein the switching valve is provided in a cylindrical shape passing through the first space and the second space, and is provided to rotate around a central axis, the switching valve is formed with: a first pas sage through which the exhaust gas introduced into the first space through the exhaust inlet flows to the exhaust outlet; and a second passage through which the outside air introduced into the second space through the outside air inlet flows to the outside air outlet, and the first passage and the second passage may be provided in a curved shape.

According to the exemplary embodiment of the present invention, further comprising: a controller, wherein, according to a property of the exhaust gas flowing in the individual exhaust pipe, the controller controls an exhaust switching module corresponding to the exhaust gas among the plurality of exhaust switching modules to be switched to the first state, and may controls the remaining exhaust switching modules except for the exhaust switching module corresponding to the exhaust gas to be switched to the second state.

According to the exemplary embodiment of the present invention, it is possible to separate and switch an exhaust path according to properties of exhaust gas.

According to the exemplary embodiment of the present invention, it is possible to prevent exhaust gas of different properties from reacting.

According to the exemplary embodiment of the present invention, it is possible to minimize contamination of an exhaust path.

According to the exemplary embodiment of the present invention, it is possible to suppress pressure fluctuation in an exhaust path.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a substrate processing apparatus according to an exemplary embodiment of the present invention.

FIG. 2 is a diagram schematically illustrating an exemplary embodiment of a liquid treating chamber of FIG. 1.

FIG. 3 is a diagram illustrating an exhaust path of a liquid treating chamber.

FIG. 4 is a perspective view illustrating a partial configuration of FIG. 3.

FIG. 5 is a diagram illustrating an exhaust switching unit of FIG. 3.

FIG. 6 is a diagram illustrating an exhaust switching module of FIG. 5.

FIG. 7 is a diagram illustrating a state in which the exhaust switching module is in a first state.

FIG. 8 is a cross-sectional view of FIG. 7.

FIG. 9 is a diagram illustrating a state of a process in which the exhaust switching module is switched from the first state to a second state.

FIG. 10 is a diagram illustrating a state when the exhaust switching module is in the second state.

FIG. 11 is a cross-sectional view of FIG. 10.

FIGS. 12 to 14 are diagrams illustrating an exemplary embodiment of switching exhaust using the exhaust switching unit of FIG. 5.

FIG. 15 is a diagram illustrating a pipe cleaning unit of FIG. 3.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, the present invention will be described based on a process of liquid-treating a substrate W by supplying a treatment onto the substrate W as an example. However, the present exemplary embodiment is not limited to the cleaning process, and may be applied to various processes of processing the substrate W using a liquid, such as an etching process, an ashing process, or a developing process.

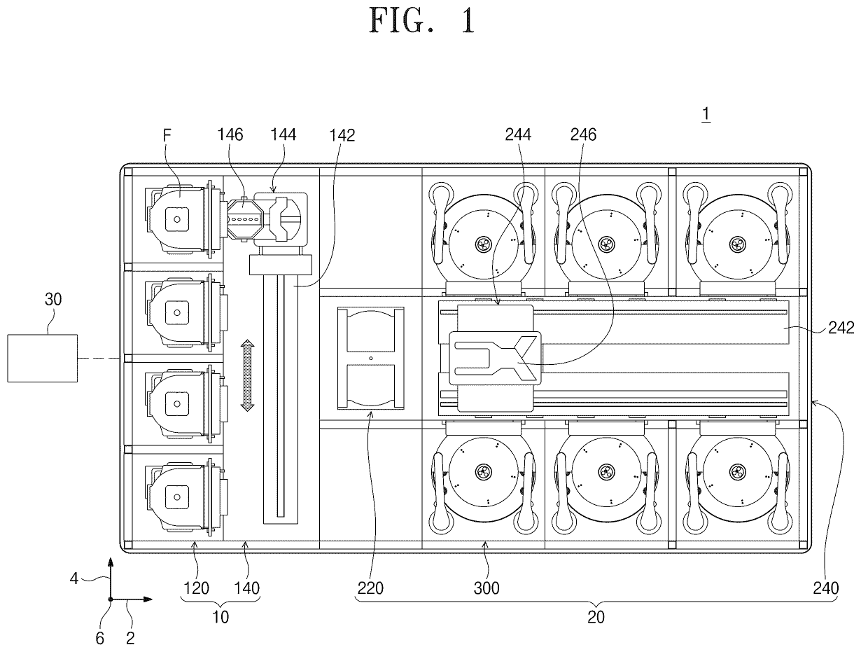

Hereinafter, an exemplary embodiment of the present invention will be described with reference to FIGS. 1 to 15. A substrate processing apparatus 1 according to an exemplary embodiment of the present invention may perform a cleaning process including a drying process of drying a substrate W using a process fluid.

FIG. 1 is a plan view schematically illustrating a substrate processing apparatus according to an exemplary embodiment of the present invention. Referring to FIG. 1, a substrate processing apparatus 1 includes an index module 10, a treating module 20, and a controller 30. According to an exemplary embodiment, the index module 10 and the treating module 20 are disposed along one direction. Hereinafter, a direction in which the index module 10 and the treating module 20 are arranged is defined as a first direction 2. When viewed from the top, a direction perpendicular to the first direction 2 is defined as a second direction 4, and a direction perpendicular to a plane including both the first direction 2 and the second direction 4 is defined as a third direction 6.

The index unit 10 transfers the substrate W from a container F in which the substrate W is accommodated to the treating unit 20 for treating the substrate W. The index module 10 accommodates the substrate W completely processed in the treating module 20 into the container F. A longitudinal direction of the index module 10 is provided in the second direction 4. The index module 10 includes a load port 120 and an index frame 140.

The container F in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction 4. The number of load ports 120 may increase or decrease according to the process efficiency and footprint conditions of the treating module 20.

A plurality of slots (not illustrated) is formed in the container F. The slots (not illustrated) may accommodate the substrates W in a state in which the substrates W are disposed horizontally with respect to the ground. As the container F, an airtight container, such as a Front Open Unified Pod (FOUP), may be used. The container F may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction 4 in its longitudinal direction. The index robot 144 may transfer the substrate W. The index robot 144 may transfer the substrate W between the index module 10 and a buffer unit 220 to be described later.

The index robot 144 includes an index hand 146. The substrate W is seated on the index hand 146. The index hand 146 may be provided on the index rail 142 to be movable along the second direction 4. Accordingly, the transfer hand 146 may be moved forward and backward along the index rail 142. Also, the index hand 146 may be provided to be rotatable with respect to the third direction 6. Also, the index hand 146 may be provided to be vertically movable along the third direction 3. A plurality of index hands 146 may be provided. A plurality of transfer hands 146 may be provided to be spaced apart from each other in the vertical direction. A plurality of transfer hands 146 may move forward, backward, and rotate independently of each other.

The controller 30 controls the substrate processing apparatus 1. The controller 30 may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to a process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus 1 to perform the substrate processing method described below. For example, the controller 30 may control the configurations provided to a liquid treating chamber 300, a pipe cleaning unit 440, and an exhaust switching unit 450 to perform a substrate processing method described below.

The treating module 20 includes a buffer unit 220, a transfer frame 240, and a liquid treating chamber 300. The buffer unit 220 provides a space in which the substrate W loaded into the treating module 20 and the substrate W unloaded from the treating module 20 stay temporarily. The transfer frame 240 provides a transfer space for transferring the substrate W between the buffer unit 220 and the liquid treating chamber 300.

The liquid treating chamber 300 performs a liquid treatment process of liquid treating the substrate W by supplying a liquid onto the substrate W. The liquid treating chamber 300 may perform a cleaning process. The cleaning process may be performed in the liquid treating chamber 300. For example, the liquid treating chamber 300 may process the substrate W by supplying a chemical, a rinse liquid, and/or an organic solvent onto the substrate W. The processing of the substrate W performed in the liquid treating chamber 300 may include a spin drying treatment in which the liquid remaining on the substrate W is removed by rotating the substrate W. The buffer unit 220 may be disposed between the index frame 140 and the transfer chamber 240. The buffer unit 220 may be located at one end of the transfer frame 240. A slot (not illustrated) in which the substrate W is placed is provided in the buffer unit 220. A plurality of slots (not illustrated) is provided. A plurality of slots (not illustrated) may be disposed to be spaced apart from each other along the third direction 6. A front face and a rear face of the buffer unit 220 are opened. The front face is a face facing the index module 10, and the rear face is a face facing the transfer frame 240. The index robot 144 may approach the buffer unit 220 through the front face, and the transfer robot 244 to be described below may approach the buffer unit 220 through the rear face.

The transfer frame 240 may be provided in a longitudinal direction along the first direction 2. The liquid treating chambers 300 may be disposed on opposite sides of the transfer frame 240. The liquid treating chamber 300 may be disposed on a side portion of the transfer frame 240. The transfer frame 240 and the liquid treating chamber 300 may be disposed along the second direction 4.

According to the example, the liquid treating chambers 300 are disposed on opposite sides of the transfer frame 240. At one side of the transfer frame 240, the liquid treating chambers 300 may be provided in an array of A×B (each of A and B is 1 or a natural number larger than 1) in the first direction 2 and the third direction 6. Here, A is the number of the liquid treating chambers 300 provided in a row along the first direction 2, and B is the number of the liquid treating chambers 300 provided in a row along the third direction 6. In other words, the liquid treating chamber 300 may be stacked and disposed along the third direction 6. For example, when six liquid treating chambers 300 are provided at one side of the transfer frame 240, the liquid treating chambers 300 may be arranged in a 3×2 array. The number of liquid treating chambers 300 may increase or decrease. Unlike the above description, the liquid treating chamber 300 may be provided as a single layer on one side and opposite sides of the transfer frame 240.

The transfer frame 240 includes a guide rail 242 and a transfer robot 244. The guide rail 242 is provided within the transfer frame 240 in the first direction 2 in a longitudinal direction thereof. The transfer robot 244 may be provided on the guide rail 242 to be able to move linearly along the first direction 2. The transfer robot 244 transfers the substrate W between the buffer unit 220 and the liquid treating chamber 300.

The transfer robot 244 includes a transfer hand 246 on which the substrate W is placed. The transfer hand 246 may be provided on the guide rail 242 to be movable along the first direction 2. Accordingly, the transfer hand 246 may be moved forward and backward along the guide rail 246. In addition, the transfer hand 246 may be provided to rotate around the third direction 6 and be movable along the third direction 6. A plurality of transfer hands 246 may be provided. A plurality of transfer hands 246 may be provided to be spaced apart from each other in the vertical direction. A plurality of transfer hands 246 may move forward and backward, and rotate independently of each other.

The liquid treating chamber 300 performs a liquid treatment process on the substrate W. For example, the liquid treating chamber 300 may be a chamber for performing a cleaning process for removing process by-products or the like attached to the substrate W. The liquid treating chamber 300 may have a different structure depending on the type of process for processing the substrate W. Alternatively, each of the liquid treating chambers 300 may have the same structure.

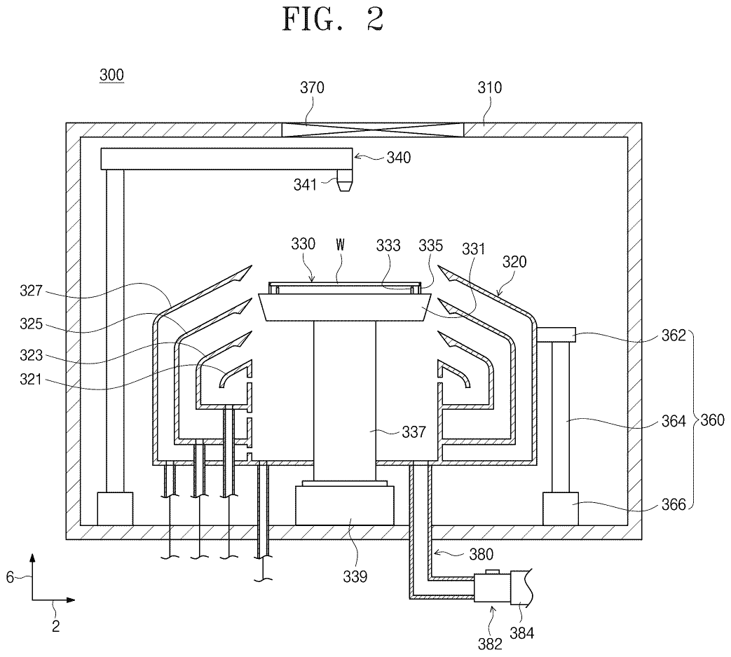

FIG. 2 is a diagram schematically illustrating the exemplary embodiment of the liquid treating chamber of FIG. 1. Referring to FIG. 2, the liquid treating chamber 300 includes a housing 310, a treating container 320, a support unit 330, and a liquid supply unit 340, an air flow supply unit 270, and an exhaust unit 380.

The housing 310 has an inner space. The housing 310 is provided in a generally rectangular parallelepiped shape. An opening (not illustrated) is formed at one side of the housing 310. The opening (not illustrated) functions as an entrance through which the substrate W is loaded in or unloaded from the inner space of the housing 310 by the transfer robot 244. The treating container 320, the support unit 330, and the liquid supply unit 340 are disposed in the inner space of the housing 310.

The treating container 320 has a treatment space with an open top. The treating container 320 may be a bowl having a treatment space. The treating container 320 may be provided to surround the treatment space. The treatment space of the treating container 320 is provided as a space in which the support unit 330 described later supports and rotates the substrate W. The treatment space is provided as a space in which the liquid supply unit 340 described later supplies a liquid onto the substrate W and processes the substrate W.

According to an example, the treating container 320 may include a guide wall 321 and a plurality of recovery containers 323, 325, and 327. Each of the recovery containers 323, 325, and 327 separates and recovers a different liquid from among liquids used for the treatment of the substrate W. Each of the recovery containers 323, 325, and 327 has a recovery space of recovering the liquid used for the processing of the substrate.

The support unit 330 supports and rotates the substrate W in the treatment space. The support unit 330 includes a spin chuck 331, a support pin 333, a chuck pin 335, a rotation shaft 337, and a driver 339.

The spin chuck 331 has a top surface that is provided in a generally circular shape when viewed from above. The top surface of the spin chuck 331 may have a larger diameter than the substrate W.

A plurality of support pins 333 is provided. The support pin 333 is disposed on the top surface of the spin chuck 331. The support pin 333 is disposed on the edge of the top surface of the spin chuck 331 to be spaced apart from each other at a predetermined interval. The support pin 333 is formed to protrude upward from the top surface of the spin chuck 331. The support pins 333 are disposed to have an annular ring shape as a whole by a combination thereof. The support pin 333 supports the edge of the back surface of the substrate W so that the substrate W is spaced apart from the top surface of the spin chuck 331 by a predetermined distance.

A plurality of chuck pins 335 is provided. The chuck pin 335 is disposed to be relatively farther from the center region of the spin chuck 331 than the support pin 333. The chuck pin 335 protrudes upward from the top surface of the spin chuck 331. The chuck pin 335 supports a side region of the substrate W so as not to be separated from the correct position in the lateral direction when the substrate W is rotated. The chuck pin 335 is provided to be able to move linearly between a standby position and a support position along a radial direction of the spin chuck 331. The standby position is defined as the position of the chuck pin 335 when the substrate W is received from the transfer robot 244 or when the substrate W is handed over to the transfer robot 244. The support position is defined as the position of the chuck pin 336 when performing a process on the substrate W. In the support position, the chuck pin 335 is in contact with the side portion of the substrate W. The standby position is provided as a position relatively far from the center of the spin chuck 331 compared to the support position.

The rotation shaft 337 is coupled to the spin chuck 331. The rotation shaft 337 is coupled to a bottom surface of the spin chuck 331. The rotation shaft 337 may be provided such that a longitudinal direction thereof faces the third direction 6. The rotation shaft 337 is provided to be rotatable by receiving power from the driver 339. The rotation shaft 337 is rotated by the driver 339, and the spin chuck 331 is rotated by the rotation shaft 337. The driver 339 rotates the rotation shaft 337. The driver 339 may vary a rotation speed of the rotation shaft 337. The driver 339 may be a motor that provides driving force. However, the present invention is not limited thereto, and may be variously modified and provided as a known device that provides driving force.

The liquid supply unit 340 supplies a treatment liquid to the substrate W. The liquid supply unit 340 supplies the treatment liquid to the substrate W supported by the support unit 330. The treatment liquid supplied by the liquid supply unit 340 to the substrate W is provided in a plurality of types. According to an example, the treatment liquid supplied by the liquid supply unit 340 to the substrate W may include a first liquid and a second liquid. The first liquid and the second liquid may be sequentially supplied to the substrate W.

The liquid supply unit 340 may include a treatment liquid supply nozzle 341.

The treatment liquid supply unit 341 supplies a treatment liquid onto the substrate W. The treatment liquid supply nozzle 341 supplies the treatment liquid onto the substrate W supported by the support unit 330.

The first liquid may be a liquid for removing a film or foreign substances remaining on the substrate W. For example, the first liquid may be a chemical including an acid or an alkali, such as sulfuric acid (H₂SO₄), nitric acid (HNO₃), or hydrochloric acid (HCl).

The second liquid may be a liquid that neutralizes the first liquid. According to an example, the second liquid may be a liquid that is easily dissolved in the process fluid. According to an example, the second liquid may be a liquid that is relatively more easily dissolved in a process fluid, such as a supercritical fluid, than the first liquid. The second liquid according to the exemplary embodiment may be an organic solvent including pure water or isopropyl alcohol (IPA).

Only one treatment liquid supply nozzle 345 is illustrated in FIG. 2, but unlike this, a plurality of treatment liquid supply nozzles 345 may be provided, and a plurality of treatment liquid supply nozzles 345 may supply a treatment liquid including the first liquid or the second liquid.

For example, the liquid supply unit 340 may include a first supply nozzle, a second supply nozzle, and a third supply nozzle. The treatment liquid supplied from the first supply nozzle to the substrate W may be chemical. The treatment liquid supplied from the second supply nozzle to the substrate W may be pure water. The treatment liquid supplied from the third supply nozzle to the substrate W may be an organic solvent including isopropyl alcohol or the like.

The lifting unit 360 is disposed in the inner space of the housing 310. The lifting unit 360 adjusts the relative height between the treating container 320 and the support unit 330. The lifting unit 360 may linearly move the treating container 320 in the third direction 6. Accordingly, the heights of the recovery tanks 323, 325, and 327 for recovering the liquid are changed according to the type of liquid supplied to the substrate W, and thus the liquids may be separated and recovered. Unlike the above description, the treating container 320 is fixedly installed, and the lifting unit 360 may change the relative height between the support unit 330 and the treating container 320 by moving the support unit 330 in the vertical direction.

The airflow supply unit 370 supplies airflow to the inner space of the housing 310. The airflow supply unit 370 may supply descending airflow to the inner space. The airflow supply unit 370 may be provided as a fan filter unit. The airflow supply unit 370 may include a fan (not illustrated) for generating airflow and a filter (not illustrated) for filtering air. The airflow supply unit 370 may be installed on an upper portion of the housing 310. Gas supplied to the inner space of the housing 310 through the airflow supply unit 370 forms descending airflow in the inner space. By-products or the like generated in the treatment space during the process proceeding are discharged to the outside of the housing 310 through an exhaust unit (not illustrated) by descending airflow formed in the inner space and the treatment space.

The exhaust unit 380 exhausts process by-products, such as fumes and gas, generated in the treatment space. Process by-products, such as fumes and gas, generated when the substrate W is liquid-treated are exhausted by a pressure reducing unit (not illustrated) provided in the exhaust unit 380. The exhaust unit 380 may be coupled to the bottom surface of the treating container 320. For example, the exhaust unit 380 may be disposed in the space between the rotation shaft 337 and the inner wall of the treating container 320.

The exhaust unit 380 may include an exhaust adjusting unit 382, an exhaust duct 384, and a drainage pipe 386. The exhaust adjusting unit 382 may adjust a flow rate of the exhaust gas flowing in the exhaust duct 384. The exhaust adjusting unit 382 may perform a function of a damper which adjusts an intake pressure of the exhaust unit 380 or the like. The exhaust adjusting unit 382 may minimize a change in pressure inside the liquid treating chamber 300 by adjusting an intake pressure of the exhaust unit 380, or the like. For example, when a pressure difference between the individual exhaust pipe 430 to be described below and the liquid treating chamber 300 is large, a change in pressure inside the liquid treating chamber 300 may be minimized by adjusting the intake pressure of the exhaust unit 380 or the exhaust flow rate through the exhaust unit 380.

The exhaust duct 384 is a configuration connecting the individual exhaust pipe 430 to be described later with the liquid treating chamber 300. The exhaust duct 384 and the individual exhaust pipe 430 may be connected to the drainage pipe 386. The drainage pipe 386 may discharge a treatment liquid in the liquid treating chamber 300 or a liquid in the individual exhaust pipe 430 to the outside.

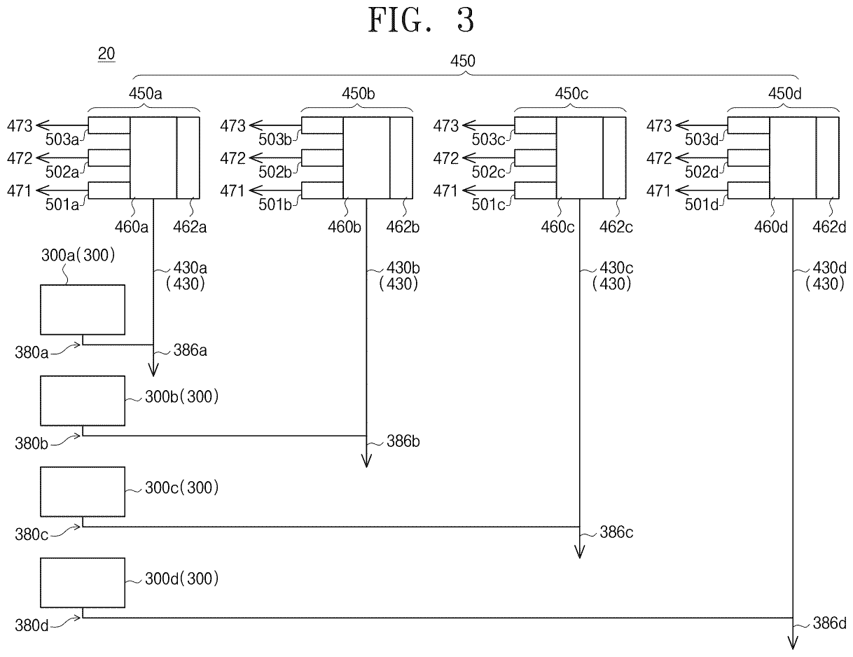

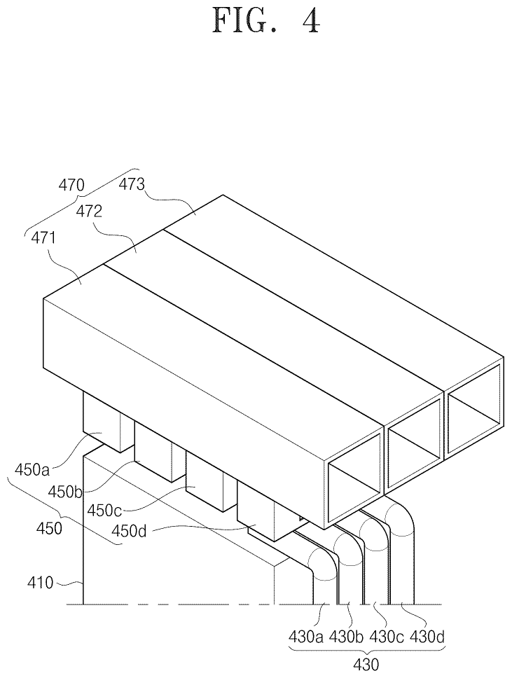

FIG. 3 is a diagram illustrating an exhaust path of the liquid treating chamber, and FIG. 4 is a perspective view illustrating a partial configuration of FIG. 3. Hereinafter, the exhaust path of the liquid treating chamber 300 of the treatment module 20 will be described with reference to FIGS. 3 and 4.

In FIGS. 3 and 4, the configurations necessary for the exhaust path of the liquid treating chamber 300 of FIG. 2 are illustrated, and the components irrelevant to the exhaust path are appropriately omitted.

The exhaust path may include the liquid treating chamber 300, the individual exhaust pipe 430, the exhaust switching unit 450, and a collective exhaust pipe 470.

The liquid treating chamber 300 is connected to the exhaust switching unit 450 through the individual exhaust pipe 430, and the exhaust switching unit 450 is connected to the collective exhaust pipe 470.

The liquid treating chamber 300 may be connected to the individual exhaust pipe 430. The exhaust unit 380 of the liquid treating chamber 300 may be connected to the individual exhaust pipe 430. The individual exhaust pipe 430 may transmit the exhaust gas discharged from the corresponding liquid treating chamber 300 to the corresponding exhaust switching unit 450. The individual exhaust pipe 430 may guide the exhaust gas discharged from the liquid treating chamber 300 to the exhaust switching unit 450. The liquid in the atmosphere discharged from the liquid treating chamber 300 to the individual exhaust pipe 430 may be discharged to the outside along the drainage pipe 386.

The exhaust switching unit 450 may separate the exhaust gas flowing in the individual exhaust pipe 430 and discharge the separated exhaust gas to the corresponding collective exhaust pipe 470. The exhaust switching unit 450 may switch the exhaust path such that the exhaust gas is discharged to any one of the plurality of collective exhaust pipes 470 according to properties of the exhaust gas flowing in the individual exhaust pipe 430. The exhaust switching unit 450 will be described later.

The plurality of collective exhaust pipes 470 may be configured. The collective exhaust pipe 470 may be a pipe having a rectangular cross-sectional shape of the inner passage. Alternatively, the cross-sectional shape of the inner passage of the collective exhaust pipe 470 may be provided in various shapes, such as a circle. The collective exhaust pipe 470 may be provided in a number corresponding to the number of properties of the exhaust gas discharged from the liquid treating chamber 300. For example, when the exhaust gas discharged from the liquid treating chamber 300 includes the exhaust gas of a first property, a second property, and a third property, the collective exhaust pipe 470 may be composed of three collective exhaust pipes 470 of a first collective pipe 471, a second collective pipe 472, and a third collective pipe 473, and may constitute an exhaust path for separating and discharging the exhaust gas of the first property, the second property, and the third property.

The exhaust gas exhausted from the liquid treating chamber 300 through the exhaust unit 380 passes through the exhaust switching unit 450 through the individual exhaust pipe 430 and is discharged to the corresponding collective exhaust pipe 470 according to the property of the exhaust gas.

When the plurality of liquid treating chambers 300 is provided, a plurality of individual exhaust pipes 430 and a plurality of exhaust switching units 450 may be provided to correspond to the plurality of liquid treating chambers 300, respectively.

In the exemplary embodiment illustrated in FIG. 3, four liquid treating chambers 300 are illustrated, and four individual exhaust pipes 430 and four exhaust switching units 450 corresponding to the liquid treating chambers 300, respectively, are illustrated. The liquid treating chambers 300a, 300b, 300c, and 300d are connected to corresponding individual exhaust pipes 430a, 430b, 430c, and 430d, respectively, and the individual exhaust pipes 430a, 430b, 430c, and 430d are connected to corresponding exhaust switching units 450a, 450b, 450c, and 450d, respectively. The numbers of liquid treating chamber 300, individual exhaust pipes 430, and exhaust switching units 450 may be changed differently from the exemplary embodiment of FIG. 3.

Each of the plurality of exhaust switching units 450a, 450b, 450c, and 450d is connected to the plurality of collective exhaust pipes 471, 472, and 473. The plurality of exhaust switching units 450a, 450b, 450c, and 450d may switch an exhaust path of the exhaust gas to the collective exhaust pipe 470 for discharging the exhaust gas of a corresponding property from among the plurality of collective exhaust pipes 471, 472, and 473 according to the properties of the exhaust gas flowing through the individual exhaust pipes 430a, 430b, 430c, and 430d.

For example, when the exhaust gas of the first property flows through the individual exhaust pipes 430a, 430b, 430c, and 430d, the exhaust switching units 450a, 450b, 450c, and 450d may discharge the exhaust gas of the first property through the first collective pipe 471 by switching the exhaust path. Alternatively, when the exhaust gas of the second property flows through the individual exhaust pipes 430a, 430b, 430c, and 430d, the exhaust switching units 450a, 450b, 450c, and 450d may discharge the exhaust gas of the second property through the second collective pipe 472 by switching the exhaust path.

A plurality of liquid treating chambers 300 may be stacked and disposed inside the frame 410. In other words, the frame 410 may provided to surround the plurality of liquid treating chambers 300. The exhaust switching unit 450 and the collective exhaust pipe 470 may be disposed above the frame 410. The collective exhaust pipe 470 may be disposed above the exhaust switching unit 450.

A plurality of exhaust switching units 450a, 450b, 450c, and 450d may be arranged side by side in one direction. The first collective pipe 471, the second collective pipe 472, and the third collective pipe 473 may be arranged side by side in one direction. Each collective exhaust pipe 470 may be arranged along a direction in which a plurality of exhaust switching units 450a, 450b, 450c, and 450d are arranged side by side. A direction in which the first collective pipe 471, the second collective pipe 472, and the third collective pipe 473 are arranged side by side may be perpendicular to a direction in which a plurality of exhaust switching units 450a, 450b, 450c, and 450d are arranged side by side.

The collective exhaust pipe 470 may be connected to all of the plurality of exhaust switching units 450a, 450b, 450c, and 450d. In other words, each of the first collective pipe 471, the second collective pipe 472, and the third collective pipe 473 may be provided to communicate with the plurality of exhaust switching units 450a, 450b, 450c, and 450d.

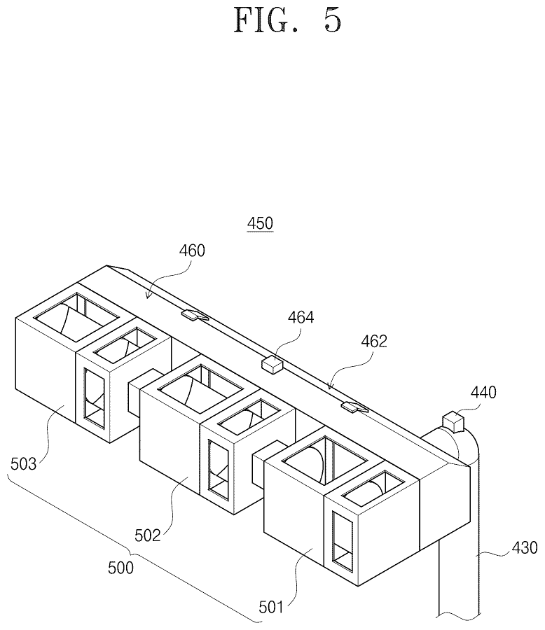

FIG. 5 is a diagram illustrating the exhaust switching unit of FIG. 3.

Hereinafter, the exhaust switching unit 450 of FIG. 3 will be described in detail with reference to FIG. 5.

The exhaust switching unit 450 may separate the exhaust gas flowing in the individual exhaust pipe 430 according to the property of the exhaust gas and discharge the exhaust gas to the corresponding collective exhaust pipe 470. The exhaust switching unit 450 may switch an exhaust path such that the exhaust gas is discharged to any one of a plurality of collective exhaust pipes 470 according to the property of the exhaust gas flowing in the individual exhaust pipe 430.

The exhaust switching unit 450 includes a buffer module 460 and an exhaust switching module 500.

The buffer module 460 includes a buffer space 461 therein.

The buffer space 461 is connected to the individual exhaust pipe 430 and the exhaust switching module 500.

The exhaust gas introduced into the buffer space 461 of the buffer module 460 may be introduced into the corresponding exhaust switching module 500 according to properties of the exhaust gas. The exhaust gas introduced into the buffer space 461 from the individual exhaust pipe 430 may be discharged to the collective exhaust pipe 470 through the exhaust switching module 500.

The buffer module 460 may include an outside air compensation module 462. The outside air compensation module 462 may introduce outside air into the buffer space 461. The outside air compensation module 462 may include a driver 464. The driver 464 may open one side of the buffer space 461 to introduce outside air into the buffer space 461.

The plurality of exhaust switching modules 500 may be provided. The exhaust switching module 500 may be provided in the number corresponding to the number of properties of the exhaust gas discharged from the liquid treating chamber 300. The exhaust switching module 500 may be provided in the same number as the number of collective exhaust pipes 470. The plurality of exhaust switching modules 500 may be disposed between the individual exhaust pipe 430 and the plurality of collective exhaust pipes 470. The buffer space 461 may be provided between the individual exhaust pipe 430 and the plurality of exhaust switching modules 500. For example, in the present exemplary embodiment, when the collective exhaust pipe 470 includes the first collective pipe 471, the second collective pipe 472, and the third collective pipe 473, the exhaust switching module 500 may be provided with a first exhaust switching module 501, a second exhaust switching module 502, and a third exhaust switching module 503, and the first exhaust switching module 501, the second exhaust switching module 502, and the third exhaust switching module 503 may constitute exhaust paths for separating and discharging the exhaust gas of the first property, the second property, and the third property into the corresponding collective exhaust pipes 470.

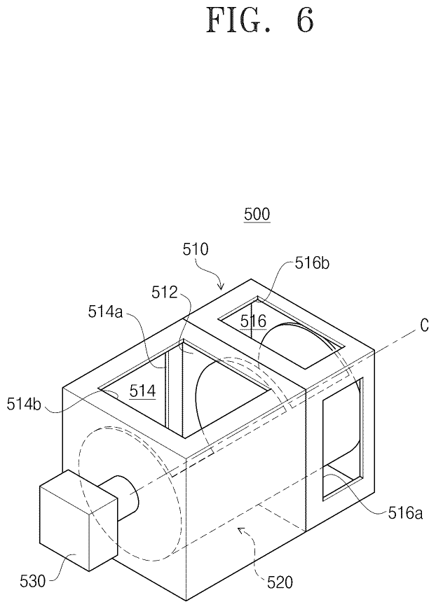

FIG. 6 is a diagram illustrating the exhaust switching module of FIG. 5.

Hereinafter, any one exhaust switching module 500 of the exhaust switching modules 501, 502, and 503 of FIG. 5 will be described in detail with reference to FIG. 6. The exhaust switching modules 501, 502, and 503 may all have the same configuration.

Referring to FIG. 6, the exhaust switching module 500 includes a housing 510, a switching valve 520, and a valve driver 530.

The housing 510 is provided in a generally rectangular parallelepiped shape. The housing 510 has an inner space. The housing 510 may have a first space 514 and a second space 516 therein. The housing 510 includes a partition wall 512. The first space 514 and the second space 516 may be partitioned from each other by the partition wall 512. The first space 514 may be provided as a space communicating with the corresponding individual exhaust pipe 430 through the buffer module 460, and the second space 516 may be provided as a space through which outside air may be introduced.

An exhaust inlet 514a, an exhaust outlet 514b, an outside air inlet 516a, and an outside air outlet 516b may be provided in the housing 510. The exhaust inlet 514a and the exhaust outlet 514b may be provided in the first space 514, and the outside air inlet 516a and the outside air outlet 516b may be provided in the second space 516.

The exhaust inlet 514a may be formed at one side of the first space 514 of the housing 510. The exhaust inlet 514a may be provided as an opening and may communicate with the buffer space 461 of the buffer module 460. The exhaust inlet 514a may be formed at one sidewall of the region in which the first space 514 of the housing 510 is formed.

The exhaust outlet 514b may be formed at one side of the first space 514 of the housing 510. For example, the exhaust outlet 514b may be formed at an upper wall of the region of the housing 510 in which the first space 514 is formed. The exhaust outlet 514b may be provided as an opening and may communicate with the collective exhaust pipe 470 connected to the exhaust switching module 500. The exhaust outlet 514b may communicate with the collective exhaust pipe 470 according to properties of the exhaust gas treated by the exhaust switching module 500. For example, the exhaust outlet 514b of the first exhaust switching module 501 for treating the exhaust gas of the first property of the exhaust switching module 500 may communicate with the first collective pipe 471. The exhaust outlet 514b of the second exhaust switching module 502 for treating the exhaust gas of the second property of the exhaust switching module 500 may communicate with the second collective pipe 472. The exhaust outlet 514b of the third exhaust switching module 503 for treating the exhaust gas of the third property of the exhaust switching module 500 may communicate with the third collective pipe 473.

The outside air inlet 516a may be formed at one side of the second space 516 of the housing 510. The outside air inlet 516a is provided as an opening and is directly exposed to ambient. The outside air inlet 516a may directly communicate with outside air. The outside air inlet 516a may be formed on one sidewall of a region in which the second space 516 of the housing 510 is formed. The surface in which the outside air inlet 516a is formed in the housing 510 may be a surface positioned opposite to the surface in which the exhaust inlet 514a is formed in the housing 510 is formed with the first space 514 and the second space 516 therebetween.

The outside air outlet 516b may be formed on one side of the second space 516 of the housing 510. For example, the outside air outlet 516b may be formed at an upper wall of the region in which the second space 516 of the housing 510 is formed. The outside air outlet 516b may be provided as an opening to communicate with the collective exhaust pipe 470 connected to the exhaust switching module 500. The outside air outlet 516b may communicate with the collective exhaust pipe 470 according to properties of the exhaust gas treated by the exhaust switching module 500. The exhaust outlet 514b and the outside air outlet 516b may communicate with the same collective exhaust pipe 470, and as described later, as the exhaust switching module 500 is switched between a first state S1 and a second state S2, outside air or exhaust gas may be discharged to the collective exhaust pipe 470.

The switching valve 520 may be provided in the housing 510. The switching valve 520 may be a cylindrical valve provided in a cylindrical shape. The switching valve 520 may be provided in a shape passing through the partition wall 512, the first space 514, and the second space 516 of the housing 510. The switching valve 520 may pass through the partition wall 512, but a partition may be formed in the switching valve 520 in a direction parallel to the partition wall 512 to partition the first space 514 and the second space 516. The switching valve 520 may be provided to be rotatable about the central axis C. The central axis C may be provided in a direction parallel to a direction in which the first space 514, the partition wall 512, and the second space 516 are arranged. The central axis C may be located at the center of a circle of the cross section of the switching valve 520 that is cut into a plane perpendicular to the central axis C.

The switching valve 520 may have a first groove 522 and a second groove 524. The first groove 522 may be formed in a region of the switching valve 520 provided in the first space 514, and the second groove 524 may be formed in a region of the switching valve 520 provided in the second space 516. The first groove 522 may be a passage through which exhaust gas flows, and the second groove 524 may be a passage through which outside air flows. In other words, the first groove 522 may serve as a first passage through which the exhaust gas flows in the first space 514b so that the exhaust gas introduced into the first space 514 through the exhaust inlet 514a of the housing 510 may be discharged to the exhaust outlet 514b. The second groove 524 may serve as a second passage through which the outside air flows in the second space 516 so that the outside air introduced into the second space 516 through the outside air inlet 516a of the housing 510 may be discharged to the outside air outlet 516b.

The switching valve 520 may be provided to be rotatable in the housing 510. As the switching valve 520 rotates in the housing 510, the switching valve 520 may move between positions that open or close the exhaust inlet 514a. As the switching valve 520 rotates inside the housing 510, the switching valve 520 may move between positions that open or close the outside air inlet 516a.

The valve driver 530 may rotate the switching valve 520. The valve driver 530 may be installed at one side of the housing 510. The valve driver 530 may be coupled to the switching valve 520. The valve driver 530 may switch the exhaust switching module 500 between the first state S1 and the second state S2 by rotating the switching valve 520 around the central axis C. The valve driver 530 may change the positions of the first groove 522 and the second groove 524 of the switching valve 520 by rotating the switching valve 520. For example, the valve driver 530 may be a rotary cylinder, but is not limited thereto and may be provided as various driving devices capable of rotating the switching valve 520.

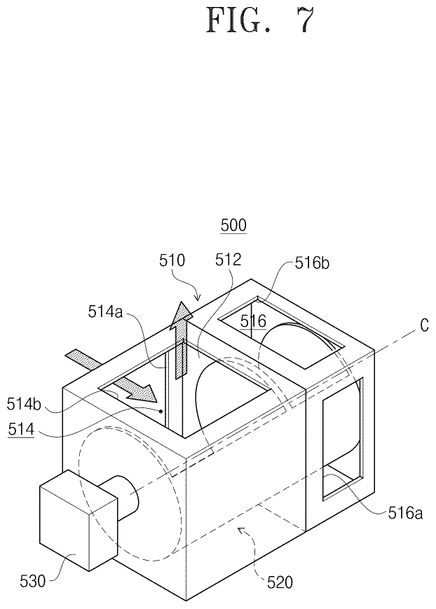

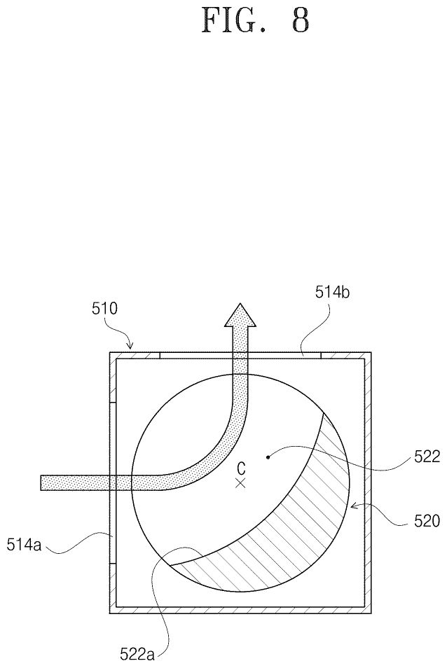

FIG. 7 is a diagram illustrating a state in which the exhaust switching module is in the first state, and FIG. 8 is a cross-sectional view of FIG. 7. Hereinafter, the operation when the exhaust switching module 500 is in the first state S1 will be described in detail with reference to FIGS. 7 and 8.

Referring to FIG. 7, when the exhaust switching module 500 is in the first state S1, the exhaust switching module 500 may communicate a corresponding individual exhaust pipe 430 with a corresponding collective exhaust pipe 470. When the exhaust switching module 500 is in the first state S1, the exhaust gas exhausted from the liquid treating chamber 300 may be discharged from the individual exhaust pipe 430 through the buffer space 461 of the exhaust switching unit 450 and the exhaust switching module 500 to the collective exhaust pipe 470.

When the exhaust switching module 500 is in the first state S1, the exhaust inlet 514a may open and the outside air inlet 516a may be closed. In other words, when the exhaust switching module 500 is in the first state S1, the first groove 522 may be disposed to communicate with the exhaust inlet 514a and the exhaust outlet 514b, and the second groove 524 may be disposed not to communicate with the outside air inlet 516a.

FIG. 8 illustrates a cross-sectional view of the first space 514 when the exhaust switching module 500 is in the first state S1. Referring to FIG. 8, exhaust gas is introduced from the individual exhaust pipe 430 into the exhaust switching module 500 through the buffer space 461 of the buffer module 460. The exhaust gas is introduced into the first space 514 through the exhaust inlet 514a, is guided to the exhaust outlet 514b through the first groove 522 of the switching valve 520, and is discharged to the collective exhaust pipe 470 through the exhaust outlet 514b.

The first groove 522 may have a corner 522a formed in a curved shape. Since the first groove 522 is provided in a curved shape, resistance applied to the exhaust gas when the exhaust gas flows along the first groove 522 may be minimized. Accordingly, the pressure fluctuation of the exhaust gas may be minimized, and the flow efficiency of the exhaust gas may be improved.

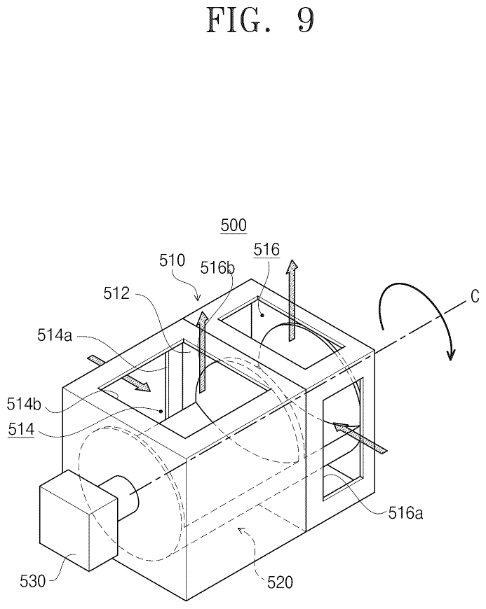

FIG. 9 is a diagram illustrating a state of a process in which the exhaust switching module is switched from the first state to the second state.

Referring to FIG. 9, the valve driver 530 may change the exhaust switching module 500 from the first state S1 to the second state S2 by rotating the switching valve 520 about the central axis C. As the valve driver 530 rotates the switching valve 520, the locations of the first groove 522 and the second groove 524 of the switching valve 520 are changed, and the exhaust switching module 500 may be switched from the first state S1 to the second state S2. In the present exemplary embodiment, the switching valve 520 may be rotated by 90° about the central axis C to be switched from the first state S1 to the second state S2.

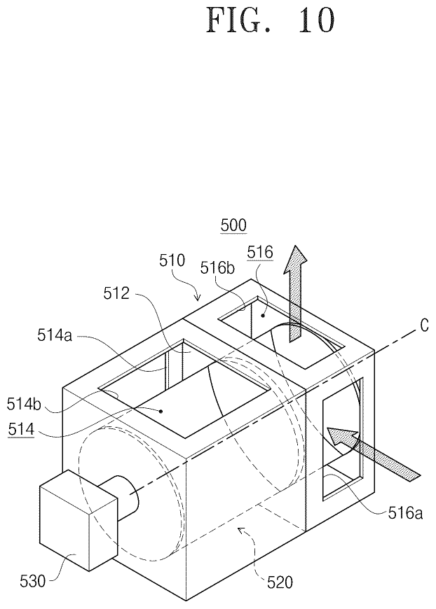

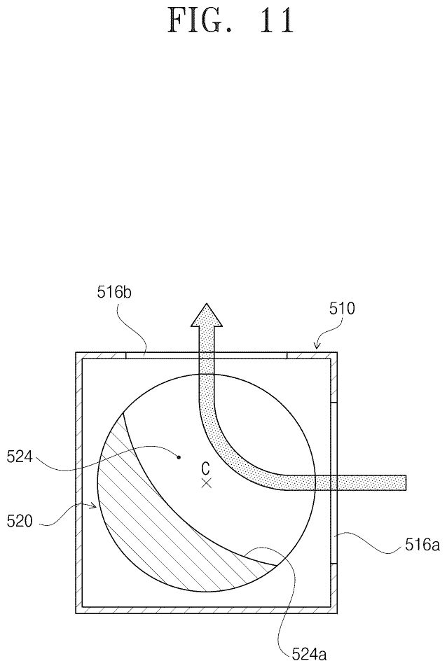

FIG. 10 is a diagram illustrating a state in which the exhaust switching module is in the first state, and FIG. 11 is a cross-sectional view of FIG. 10.

Hereinafter, the operation when the exhaust switching module 500 is in the second state S2 will be described in detail with reference to FIGS. 9 and 10.

Referring to FIG. 9, when the exhaust switching module 500 is in the second state S2, the exhaust switching module 500 may enable the outside to communicate with the collective exhaust pipe 470. When the exhaust switching module 500 is in the second state S2, the exhaust switching module 500 may discharge the outside air to the corresponding collective exhaust pipe 470. When the exhaust switching module 500 is in the second state S2, the outside air may be introduced into the second space 516 of the exhaust switching module 500 through the outside air inlet 516a exposed to the outside and may be discharged to the collective exhaust pipe 470 through the exhaust switching module 500.

When the exhaust switching module 500 is in the second state S2, the outside air inlet 516a may be opened and the exhaust inlet 514a may be closed. In other words, when the exhaust switching module 500 is in the second state S2, the first groove 522 may be disposed not to communicate with the exhaust inlet 514a and the exhaust outlet 514b and the second groove 524 may be disposed to communicate with the outside air inlet 516a and the outside air outlet 516b according to the rotation of the switching valve 520.

FIG. 10 is a cross-sectional view of the second space 516 when the exhaust switching module 500 is in the second state S2. Referring to FIG. 10, outside air is introduced into the second space 516 of the exhaust switching module 500 through the outside air inlet 516a communicating with the outside, is guided to the outside air outlet 516b through the second groove 524 of the switching valve 520, and is discharged to the collective exhaust pipe 470 through the outside air outlet 516b.

The second groove 524 may have a corner 524a formed in a curved shape. Since the second groove 524 is provided in a curved shape, resistance applied to the outside air when the outside air flows along the second groove 524 may be minimized. Accordingly, the pressure fluctuation of the outside air may be minimized, and the flow efficiency of the outside air may be improved.

Referring back to FIG. 9, when the exhaust switching module 500 is in the second state S2, exhaust gas introduced from the individual exhaust pipe 430 into the buffer space 461 of the buffer module 460 is not introduced into the exhaust switching module 500 because the exhaust inlet 514a is closed. In this case, exhaust gas may be introduced into another exhaust switching module 500 with the exhaust inlet 514a open among a plurality of exhaust switching modules 501, 502, and 503. This will be described later.

Referring back to FIG. 8, while the valve driver 530 rotates the switching valve 520 around the central axis C to switch the exhaust switching module 500 from the first state S1 to the second state S2, the first groove 522 may be disposed to communicate with the exhaust inlet 514a and the exhaust outlet 514b, and the second groove 524 may be disposed to communicate with the outside air inlet 516a and the outside air outlet 516b.

For example, in the process of switching the exhaust switching module 500 from the first state S1 to the second state S2 according to the rotation of the switching valve 520, the area of the passage through which the exhaust inlet 514a and the first groove 522 communicate may gradually decrease according to the rotation movement of the first groove 522, and the exhaust inlet 514a may be switched from an open state to a closed state. The exhaust gas is introduced into the first space 514 through the exhaust inlet 514a, is guided to the exhaust outlet 514b through the first groove 522 of the switching valve 520, and is discharged to the collective exhaust pipe 470 through the exhaust outlet 514b. In this process, the flow rate of the exhaust gas introduced into the first space 514 may be gradually decreased as the flow rate of the exhaust gas is switched from the first state S1 to the second state S2.

For example, in the process of switching the exhaust switching module 500 from the first state S1 to the second state S2 according to the rotation of the switching valve 520, the area of the passage where the outside air inlet 516a and the second groove 524 communicate gradually increases according to the rotation movement of the second groove 524, and the outside air inlet 516a may be switched from the closed state to the open state. The outside air is introduced into the second space 516 through the outside air inlet 516a, is guided to the outside air outlet 516b through the second groove 524 of the switching valve 520, and is discharged to the collective exhaust pipe 470 through the outside air outlet 516b. In this process, the flow rate of the outside air flowing into the second space 516 may gradually increase as the exhaust switching module 500 is switched from the first state S1 to the second state S2.

In the process in which the exhaust switching module 500 is switched between the first state S1 and the second state S2, the flow rate of the exhaust gas discharged to the collective exhaust pipe 470 through the exhaust switching module 500 increases or decreases, so that the flow rate of the outside air discharged to the collective exhaust pipe 470 decreases or increases. Therefore, the sum of the flow rates of the exhaust gas discharged to the collective exhaust pipe 470 and the outside air does not fluctuate significantly, so that the pressure fluctuation in the collective exhaust pipe 470 may be minimized.

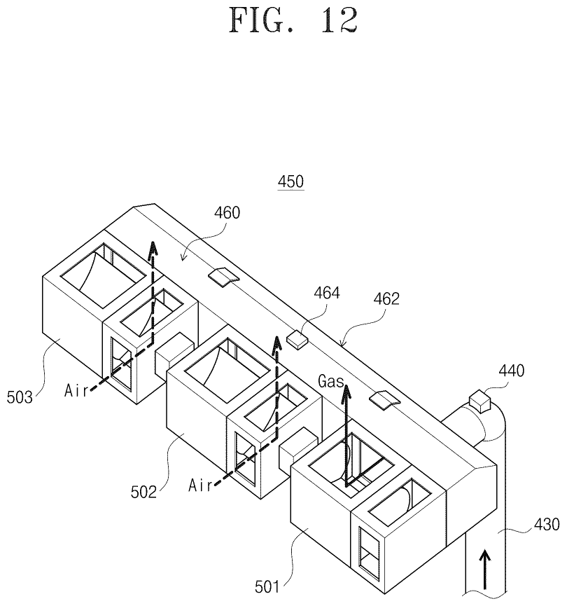

FIGS. 12 to 14 are diagrams illustrating an exemplary embodiment of switching exhaust using the exhaust switching unit of FIG. 5.

Hereinafter, a method of treating exhaust gas according to properties of exhaust gas exhausted from the liquid treating chamber 300 by the exhaust switching unit 450 of the present invention will be described in detail with reference to FIGS. 12 to 14.

Exhaust gas of different properties may be introduced into the buffer space 461 of the buffer module 460 through the exhaust unit 380 and the individual exhaust pipe 430 according to a type of a treatment liquid to be treated in the liquid treating chamber 300. The exhaust gas may be any one of acidic exhaust gas, alkaline exhaust gas, and organic exhaust gas.

FIG. 12 illustrates a state in which the first exhaust switching module 501 discharges the exhaust gas from the individual exhaust pipe 430 to the corresponding collective exhaust pipe 470, and the second exhaust switching module 502 and the third exhaust switching module 503 discharge the outside air to the corresponding collective exhaust pipe 470. For example, exhaust gas of the first property may be introduced into the buffer space 461 of the buffer module 460 through the exhaust unit 380 and the individual exhaust pipe 430 in the liquid treating chamber 300. For example, the exhaust gas of the first property may be acidic exhaust gas.

The first exhaust switching module 501 is switched to the first state S1. The exhaust gas of the first property in the buffer space 461 is introduced into the first space 514 through the exhaust inlet 514a, is guided to the exhaust outlet 514b through the first groove 522 of the switching valve 520, and is discharged to the first collective pipe 471 through the exhaust outlet 514b.

The second exhaust switching module 502 and the third exhaust switching module 503 are switched to the second state S2. The outside air is introduced into the second space 516 of the second exhaust switching module 502 and the third exhaust switching module 503 through the outside air inlet 516a communicating with the outside, is guided to the outside air outlet 516b through the second groove 524 of the switching valve 520, and is discharged to the corresponding collective exhaust pipe 470 through the outside air outlet 516b, that is, the second collective pipe 472 communicating with the second exhaust switching module 502 and the third collective pipe 473 communicating with the third exhaust switching module 503. In this case, the exhaust gas of the first property in the buffer space 461 is not introduced into the second exhaust switching module 502 and the third exhaust switching module 503.

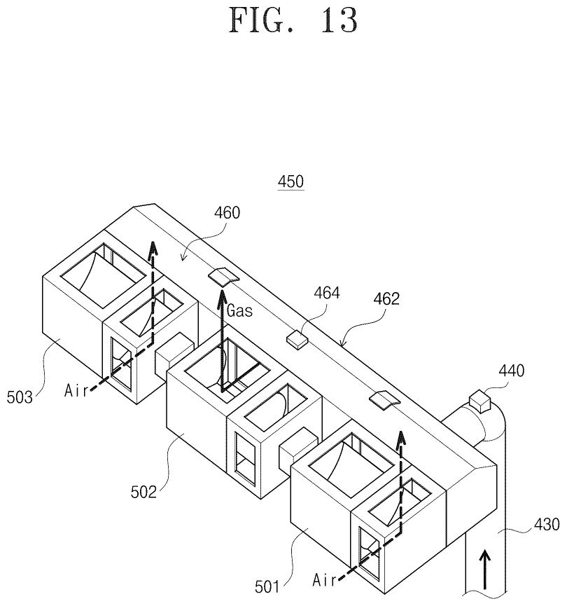

FIG. 13 illustrates the state in which the second exhaust switching module 502 exhausts the exhaust gas from the individual exhaust pipe 430 to the corresponding collective exhaust pipe 470, and the first exhaust switching module 501 and the third exhaust switching module 503 exhaust outside air to the corresponding collective exhaust pipe 470. For example, the exhaust gas of the second property may be introduced into the buffer space 461 of the buffer module 460 through the exhaust unit 380 and the individual exhaust pipe 430 in the liquid treating chamber 300. For example, the exhaust gas of the second property may be alkali-based exhaust gas.

The second exhaust switching module 502 is switched to the first state S1. The exhaust gas of the second property in the buffer space 461 is introduced into the first space 514 through the exhaust inlet 514a, is guided to the exhaust outlet 514b through the first groove 522 of the switching valve 520, and is discharged to the second collective pipe 472 through the exhaust outlet 514b.

The first exhaust switching module 501 and the third exhaust switching module 503 are switched to the second state S2. Outside air is introduced into the second space 516 of the first exhaust switching module 501 and the third exhaust switching module 503 through the outside air inlet 516a communicating with the outside, is guided to the outside air outlet 516b through the second groove 524 of the switching valve 520, and is discharged to the corresponding collective exhaust pipe 470 through the outside air outlet 516b, that is, the first collective pipe 471 communicating with the first exhaust switching module 501 and the third collective pipe 473 communicating with the third exhaust switching module 503. In this case, the exhaust gas of the second property in the buffer space 461 cannot be introduced into the first exhaust switching module 501 and the third exhaust switching module 503.

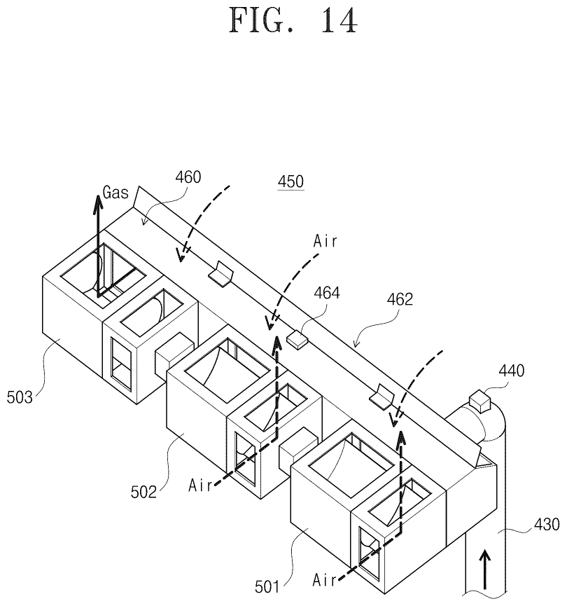

FIG. 14 illustrates the state in which the third exhaust switching module 503 exhausts the exhaust gas from the individual exhaust pipe 430 to the corresponding collective exhaust pipe 470, and the first exhaust switching module 501 and the second exhaust switching module 502 exhaust outside air to the corresponding collective exhaust pipe 470. For example, the exhaust gas of the third property may be introduced into the buffer space 461 of the buffer module 460 through the exhaust unit 380 and the individual exhaust pipe 430 in the liquid treating chamber 300. For example, an exhaust gas of the third property may be organic exhaust gas.

The third exhaust switching module 503 is switched to the first state S1. The exhaust gas of the third property in the buffer space 461 is introduced into the first space 514 through the exhaust inlet 514a, is guided to the exhaust outlet 514b through the first groove 522 of the switching valve 520, and is discharged to the third collective pipe 473 through the exhaust outlet 514b.

The first exhaust switching module 501 and the second exhaust switching module 502 are switched to the second state S2. The outside air is introduced into the second space 516 of the first exhaust switching module 501 and the second exhaust switching module 502 through the outside air inlet 516a communicating with the outside, and is guided to the outside air outlet 516b through the second groove 524 of the switching valve 520, and is discharged to the corresponding collective exhaust pipe 470 through the outside air outlet 516b, that is, the first collective pipe 471 communicating with the first exhaust switching module 501 and the second collective pipe 472 communicating with the second exhaust switching module 502. In this case, the exhaust gas of the third property in the buffer space 461 may not be introduced into the first exhaust switching module 501 and the second exhaust switching module 502.

Depending on a type of a treatment liquid treated in the liquid treating chamber 300 or a type of a substrate treatment process, characteristics or a flow rate of airflow supplied through the airflow supply unit 370 of the liquid treating chamber 300 may be changed. For example, when the amount of airflow supplied through the airflow supply unit 370 in any one liquid treating chamber 300 among the liquid treating chambers 300a, 300b, 300c, and 300d, a flow rate of the exhaust gas flowing into the individual exhaust pipe 430 through the exhaust unit 380 may be reduced. For example, in a case of a process using a low amount of exhaust, such as low-humidity Clean Dry Air (CDA) or nitrogen (N₂) through the airflow supply unit 370, a flow rate of the exhaust gas flowing into the individual exhaust pipe 430 through the exhaust unit 380 may be reduced.

As illustrated in FIG. 14, when the individual exhaust pipe 430 is connected to the third collective pipe 473 through the third exhaust switching module 503, the flow rate flowing into the third collective pipe 473 may be reduced as the flow rate of the exhaust gas of the third property flowing into the individual exhaust pipe 430 decreases, and a pressure hunting phenomenon may occur in the third collective pipe 473 or the liquid treating chamber 300. In this case, outside air may be introduced into the buffer space 461 through the outside air compensation module 462 and discharged to the third collective pipe 473 through the third exhaust switching module 503. The driver 464 of the outside air compensation module 462 may open one side of the buffer space 461 and the like to introduce outside air into the buffer space 461.

As the outside air compensation module 462 introduces outside air into the buffer space 461, it is possible to compensate for a decrease in the flow rate of the individual exhaust pipe 430 caused due to the decrease in the amount of air supplied from the liquid treating chamber 300, and to suppress pressure fluctuations in the exhaust path including the liquid treating chamber 300 and the collective exhaust pipe 470.

In the above-described exemplary embodiment, it has been illustrated that the outside air compensation module 462 introduces outside air into the buffer space 461 only when exhaust gas of the third property is introduced, but the outside air compensation module 462 may operate to compensate for the pressure reduction of the liquid treating chamber 300 and the collective exhaust pipe 470, regardless of the property of the exhaust gas.

The liquid treating chamber 300 may exhaust gas of a specific property, and the controller 30 may switch the exhaust switching module 500 corresponding to the exhaust gas of the property to the first state S1 among the plurality of exhaust switching modules 500 according to the property of the exhaust gas flowing through the individual exhaust pipe 430, and discharge the exhaust gas to the collective exhaust pipe 470, and switch the remaining exhaust switching modules 500 except for the exhaust switching module 500 corresponding to the exhaust gas of the property to the second state S2 so that outside air is introduced.

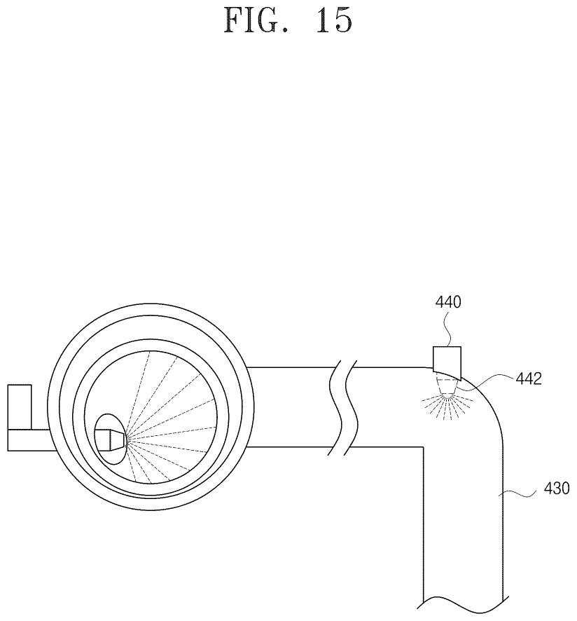

FIG. 15 is a diagram illustrating the pipe cleaning unit of FIG. 3.

Referring to FIG. 15, one or more pipe cleaning units 440 may be installed in the individual exhaust pipe 430. The pipe cleaning unit 440 includes a cleaning liquid injection nozzle 442.

The cleaning liquid injection nozzle 442 may supply a cleaning liquid into the individual exhaust pipe 430 and dissolve and remove by-products present in the individual exhaust pipe 430. The cleaning liquid injection nozzle 442 may be installed inside the individual exhaust pipe 430.

The by-products may be generated from exhaust gas generated by treating the substrate W with a treatment liquid in the liquid treating chamber 300. Components in the exhaust gas may react to cause a by-product generation reaction, and these by-products may be attached to the inside of the individual exhaust pipe 430 and thus contaminate the individual exhaust pipe 430. The cleaning liquid may be a liquid capable of dissolving a salt generated in the liquid treating chamber 300. For example, the cleaning liquid may include water.

The controller 30 may control the flow rate of the cleaning liquid supplied by the pipe cleaning unit 440. By calculating the maximum amount of by-products that may be generated inside the individual exhaust pipe 430, the amount of cleaning liquid capable of dissolving all of the maximum amount of by-products may be calculated and supplied. The flow rate of the supplied cleaning liquid may vary according to the flow rate of the treatment liquid supplied from the liquid treating chamber 300, the type of by-products, and the solubility of the by-products in the cleaning liquid.

For example, the controller 30 may calculate the number of moles of gas generated using Clausius-Clapeyron Equation and Raul's law according to the flow rate of the treatment liquid supplied from the liquid treating chamber 300, calculate the maximum amount of by-products that may be generated by assuming that all vaporized gas have caused a by-product generation reaction, and then calculate the minimum amount of cleaning liquid required for the dissolution of the by-products to control the cleaning liquid spray nozzle 442 to supply the cleaning liquid.

The pipe cleaning unit 440 may be installed at one or more points of the individual exhaust pipe 430. The pipe cleaning unit 440 may be installed at a point where there is a high possibility that by-products are generated on the path of the individual exhaust pipe 430. For example, the pipe cleaning unit 440 may be installed at a point where the flow rate or pressure of the exhaust gas flowing through the individual exhaust pipe 430 on the path of the individual exhaust pipe 430 is rapidly changed. The cleaning liquid injection nozzle 442 may clean a corresponding point by injecting the cleaning liquid to a point where the flow rate or pressure of the exhaust gas flowing through the individual exhaust pipe 430 on the path of the individual exhaust pipe 430 is rapidly changed. As illustrated in FIG. 15, the cleaning liquid injection nozzle 442 may be installed to perform horizontal injection or vertical injection.

The cleaning liquid supplied into the individual exhaust pipe 430 through the cleaning liquid injection nozzle 442 may be discharged through the drainage pipe 386. Alternatively, a path for draining the cleaning liquid inside the individual exhaust pipe 430 may be configured separately from the drainage pipe 386.

As different treatment liquids are used in the liquid treating chamber 300, properties of the exhaust gas discharged from the liquid treating chamber 300 may be different. For example, the liquid treating chamber 300 may discharge acid-based exhaust gas, alkaline-based exhaust gas, or organic exhaust gas. In this case, it is preferable that the exhaust paths of the exhaust gas of different properties are separated from each other and the exhaust gas of different properties are discharged individually to prevent the exhaust gas of different properties from reacting, secure safety, and prevent the exhaust path from being contaminated.

According to the above-described exemplary embodiment, the present invention separates the exhaust path so that the exhaust gas is exhausted through different collective exhaust pipes 470 according to the properties of the exhaust gas exhausted by the liquid treating chamber 300, while switching between the exhaust paths using the exhaust switching module 500. As exhaust gas of different properties is exhausted through different paths, reactions between different gaseous chemicals may be reduced, and by-products may be suppressed from being generated by chemical reactions or the like. According to the exemplary embodiment of the present invention, it is possible to minimize contamination of an exhaust path.

In addition, the pipe cleaning unit 440 according to the exemplary embodiment of the present invention may prevent by-products that may be generated from the atmosphere exhausted from the liquid treating chamber 300 from contaminating the inside of the individual exhaust pipe 430, thereby minimizing contamination of the exhaust path.

In the above-described exemplary embodiment, it has been illustrated and described that based on the example in which the exhaust gas discharged from the liquid treating chamber 300 has the first property, the second property, and the third property, each exhaust switching unit 450 has three exhaust switching modules 500, and three exhaust pipes 470 are provided, while each exhaust switching module 500 is configured in a one-to-one correspondence with the exhaust pipe 470, thereby forming an exhaust path, but the present invention is not limited thereto. Two or more exhaust paths may be assumed according to a property classification method of a treatment liquid and exhaust gas used in the liquid treating chamber 300, and the number of exhaust pipes 470 and exhaust switching modules 500 may also be variously changed in response to the number of exhaust paths.

In the above exemplary embodiment, it is illustrated and described that the switching valve 520 is rotated by 90° to be switched between the first state S1 and the second state S2, but the present invention is not limited thereto. The switching valve 520 may be configured to be switched between three or more states, and the switching valve 520 may be rotated at various angles depending on the arrangement of the exhaust inlet 514a, the exhaust outlet 514b, the outside air inlet 516a, the outside air outlet 516b, and the like.

Although it has been illustrated and described that the exhaust switching module 500 has the first space 514 and the second space 516, the present invention is not limited thereto. The exhaust switching module 500 may be divided into three or more spaces, and may be provided such that different types of fluids are discharged through the spaces, respectively.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. A substrate processing apparatus comprising:
a liquid treating chamber for processing a substrate with multiple types of treatment liquids;
an individual exhaust pipe connected to the liquid treating chamber to exhaust an atmosphere in the liquid treating chamber;
a plurality of collective exhaust pipes connected to the individual exhaust pipes; and
an exhaust switching unit which is disposed between the individual exhaust pipe and the collective exhaust pipe, and switches an exhaust path of the exhaust gas to a corresponding collective exhaust pipe according to the property of the exhaust gas flowing in the individual exhaust pipe,
wherein the exhaust switching unit includes an exhaust switching module disposed between the individual exhaust pipe and each of the collective exhaust pipes,
each of the exhaust switching modules includes:
a housing in which a first space and a second space separated and partitioned from each other by a partition wall are formed;
a switching valve provided inside the housing; and
a valve driver for driving the switching valve between a first state and a second state,
the first space is provided as a space capable of communicating with the individual exhaust pipe,
the second space is provided as a space through which outside air is introduced,
the first state is a state in which the exhaust switching module makes the individual exhaust pipe communicate with the collective exhaust pipe, and
the second state is a state in which the exhaust switching module makes the outside communicate with the collective exhaust pipe.

2. The substrate processing apparatus of claim 1, wherein the housing includes:
an exhaust inlet through which the exhaust gas is introduced from the individual exhaust pipe;
an exhaust outlet through which the exhaust gas introduced into the housing is discharged;
an outside air inlet through which outside air is introduced into the housing; and
an outside air outlet through which the outside air introduced into the housing is discharged,
the exhaust inlet and the exhaust outlet are provided in the first space,
the outside air inlet and the outside air outlet are provided in the second space, and
the exhaust outlet and the outside air outlet communicate with the collective exhaust pipe.

3. The substrate processing apparatus of claim 2, wherein the exhaust switching module is provided to be switched between a first state and a second state through rotation of the switching valve,
the first state is a state in which the exhaust inlet is opened and the outside air inlet is closed, and
the second state is a state in which the exhaust inlet is closed and the outside air inlet is opened.

4. The substrate processing apparatus of claim 2, wherein the switching valve is provided in a cylindrical shape passing through the first space and the second space, and is provided to rotate around a central axis.

5. The substrate processing apparatus of claim 2, wherein the switching valve is formed with:
a first passage through which the exhaust gas introduced into the first space through the exhaust inlet flows to the exhaust outlet; and
a second passage through which the outside air introduced into the second space through the outside air inlet flows to the outside air outlet.

6. The substrate processing apparatus of claim 5, wherein the first passage and the second passage of the switching valve are provided in a curved shape.

7. The substrate processing apparatus of claim 2, wherein the outside air inlet is directly exposed to ambient.

8. The substrate processing apparatus of claim 1, wherein the exhaust switching unit further includes a buffer module having a buffer space provided between the individual exhaust pipe and the plurality of exhaust switching modules.

9. The substrate processing apparatus of claim 8, wherein the buffer module includes an outside air compensation module that introduces outside air into the buffer space.

10. The substrate processing apparatus of claim 1, wherein the collective exhaust pipe includes:
a first collective pipe for exhausting acid gas;
a second collective pipe for exhausting alkaline gas; and
a third collective pipe for exhausting organic gas.

11. The substrate processing apparatus of claim 1, wherein the liquid treating chamber is provided in plural,
the plurality of liquid treating chambers is stacked and provided,
a frame surrounding the plurality of stacked liquid treating chambers is included, and the collective exhaust pipe and the exhaust switching unit are disposed above the frame.

12. The substrate processing apparatus of claim 1, further comprising:
a pipe cleaning units for cleaning the individual exhaust pipe; and
a controller,
the pipe cleaning unit includes a plurality of cleaning liquid injection nozzles that supplies a cleaning liquid to the individual exhaust pipe,
the cleaning liquid injection nozzle is installed inside the individual exhaust pipe, and
the controller calculates the amount of by-products that may be generated according to the amount of treatment liquid supplied to the liquid treating chamber, and controls the cleaning liquid injection nozzle to supply the amount of cleaning liquid needed to dissolve the calculated amount of by-products.

13. The substrate processing apparatus of claim 3, further comprising:
a controller,
wherein, according to a property of the exhaust gas flowing in the individual exhaust pipe, the controller controls an exhaust switching module corresponding to the exhaust gas among the plurality of exhaust switching modules to be switched to the first state, and controls the remaining exhaust switching modules except for the exhaust switching module corresponding to the exhaust gas to be switched to the second state.

14. The substrate processing apparatus of claim 9, further comprising:
a controller,
when a flow rate of the exhaust gas introduced into the buffer space from the individual exhaust pipe is reduced, the controller controls the reduced flow rate to be compensated by introducing outside air into the buffer space through the outside air compensation module.

15. An exhaust switching unit that is connected to an individual exhaust pipe and separates and discharges exhaust gas according to a property of the exhaust gas flowing in the individual exhaust pipe, the exhaust switching unit comprising:
a plurality of exhaust switching modules provided to correspond to the property of the exhaust gas,
wherein each of the exhaust switching modules includes:
a housing in which a first space and a second space separated and partitioned from each other are formed;
a switching valve provided inside the housing; and
a valve driver for driving the switching valve between a first state and a second state,
the housing includes:
an exhaust inlet through which the exhaust gas is introduced from the individual exhaust pipe;
an exhaust outlet through which the exhaust gas introduced into the housing is discharged;
an outside air inlet through which outside air is introduced into the housing; and
an outside air outlet through which the outside air introduced into the housing is discharged,
the exhaust inlet and the exhaust outlet are provided in the first space,
the outside air inlet and the outside air outlet are provided in the second space,
the switching valve is provided in a cylindrical shape passing through the first space and the second space,
the switching valve is formed with:
a first groove that is a first passage through which the exhaust gas introduced into the first space through the exhaust inlet flows to the exhaust outlet; and
a second groove that is a second passage through which the outside air introduced into the second space through the outside air inlet flows to the outside air outlet, and
the first groove and the second groove are provided in a curved shape.

16. The exhaust switching unit of claim 15, wherein the exhaust switching module is provided to be switched between the first state and the second state through rotation of the switching valve,
the switching valve is provided to rotate around a central axis,
the first state is a state in which the exhaust inlet and the exhaust outlet are opened and the outside air inlet and the outside air outlet are closed, and
the second state is a state in which the exhaust inlet and the exhaust outlet are closed and the outside air inlet and the outside air outlet are opened.

17. The exhaust switching unit of claim 15, further comprising:
a buffer module having a buffer space provided between the individual exhaust pipe and the plurality of exhaust switching modules,
wherein the buffer module includes an outside air compensation module that introduces outside air into the buffer space.

18. A substrate processing apparatus comprising:
a liquid treating chamber for processing a substrate with multiple types of treatment liquids;
an individual exhaust pipe connected to the liquid treating chamber to exhaust an atmosphere in the liquid treating chamber;
a plurality of collective exhaust pipes connected to the individual exhaust pipe to exhaust exhaust gas exhausted from a plurality of liquid treating chambers; and
an exhaust switching unit which is connected to the individual exhaust pipe and the collective exhaust pipe and switches an exhaust path of the exhaust gas to a collective exhaust pipe corresponding to the exhaust gas according to a property of the exhaust gas flowing in the individual exhaust pipe,
the liquid treating chamber and the individual exhaust pipe are provided in plural,
the exhaust switching unit connects each of the individual exhaust pipes to the collective exhaust pipe,
the exhaust switching unit includes:
a plurality of exhaust switching modules provided to correspond to the property of the exhaust gas; and
a buffer module having a buffer space provided between the individual exhaust pipe and the plurality of exhaust switching modules,
each of the exhaust switching modules includes:
a housing in which a first space and a second space separated and partitioned from each other are formed;
a switching valve provided inside the housing; and
a valve driver which drives the switching valve between a first state and a second state,
the housing includes:
an exhaust inlet through which the exhaust gas is introduced from the individual exhaust pipe;
an exhaust outlet through which the exhaust gas introduced into the housing is discharged;
an outside air inlet through which outside air is introduced into the housing; and
an outside air outlet through which the outside air introduced into the housing is discharged,
the exhaust inlet and the exhaust outlet are provided in the first space,
the outside air inlet and the outside air outlet are provided in the second space,
the exhaust outlet and the outside air outlet communicate with the collective exhaust pipe,
the exhaust switching module is provided to be switched between the first state and the second state through rotation of the switching valve,
the first state is a state in which the exhaust inlet and the exhaust outlet are opened and the outside air inlet and the outside air outlet are closed,
the second state is a state in which the exhaust inlet and the exhaust outlet are closed and the outside air inlet and the outside air outlet are opened, and
the buffer module includes an outside air compensation module that introduces outside air into the buffer space.

19. The substrate processing apparatus of claim 18, wherein the switching valve is provided in a cylindrical shape passing through the first space and the second space, and is provided to rotate around a central axis,
the switching valve is formed with:
a first passage through which the exhaust gas introduced into the first space through the exhaust inlet flows to the exhaust outlet; and
a second passage through which the outside air introduced into the second space through the outside air inlet flows to the outside air outlet, and
the first passage and the second passage are provided in a curved shape.

20. The substrate processing apparatus of claim 18, further comprising:
a controller,
wherein, according to a property of the exhaust gas flowing in the individual exhaust pipe, the controller controls an exhaust switching module corresponding to the exhaust gas among the plurality of exhaust switching modules to be switched to the first state, and controls the remaining exhaust switching modules except for the exhaust switching module corresponding to the exhaust gas to be switched to the second state.
